(19) United States
(12) Patent Application Publication
(10) Pub. No.: US 2025/0306319 A1
(43) Pub. Date: Oct. 2, 2025

(54) OPTICAL WAVEGUIDE PACKAGE AND LIGHT-EMITTING DEVICE

(71) Applicant: KYOCERA Corporation, Kyoto-shi (JP)

(72) Inventors: Yoshiaki ITAKURA, Aira-shi (JP); Yasuhiro FUJIMOTO, Setouchi-shi (JP); Hiroki ITO, Kirishima-shi (JP)

(73) Assignee: KYOCERA Corporation, Kyoto-shi (JP)

(21) Appl. No.: 18/960,300

(22) Filed: Nov. 26, 2024

Related U.S. Application Data
(63) Continuation-in-part of application No. 17/760,780, filed on Mar. 16, 2022, now Pat. No. 12,181,723.

(30) Foreign Application Priority Data
Sep. 30, 2019 (JP) 2019-180925

(51) Int. Cl. G02B 6/43; G02B 6/42; H10F 55/155

(52) U.S. Cl. CPC G02B 6/43; G02B 6/4239; G02B 6/426; H10F 55/155; G02B 6/4245; G02B 6/4274

(57) ABSTRACT

An optical waveguide package includes a substrate, a cladding on the substrate, a core in the cladding, and a metal member. The cladding includes a first surface facing the substrate, a second surface, and an element-receiving area being open in the second surface. The core includes a first incident end face and a second incident end face exposed in the element-receiving area, and an emission end face connected to the first incident end face and the second incident end face with a waveguide. The metal member is located on the second surface and surrounds the element-receiving area. The waveguide includes a first branching path connected to the first incident end face, a second branching path connected to the second incident end face, and a merging portion merging the first branching path and the second branching path. The merging portion is outside an area surrounded by the metal member.

### CROSS-REFERENCE TO RELATED APPLICATION

This application is a continuation-in-part application of U.S. patent application Ser. No. 17/760,780, which is a U.S. national phase application of International Application No. PCT/JP2020/021247 filed on May 28, 2020 claiming priority to Japanese Patent Application No. 2019-180925 filed on Sep. 30, 2019, the entire disclosure of which is incorporated herein by reference.

### BACKGROUND OF INVENTION

### Field of Invention

The present disclosure relates to an optical waveguide package and a light-emitting device.

### Description of Related Art

A known optical waveguide package and a light-emitting device including the optical waveguide package are described in, for example, Patent Literature 1 (Japanese Patent No. 3324936). The known structure includes a substrate, a cladding layer on the substrate, a laser diode (LD) and a photodiode (PD) in etched portions in the cladding layer, and a lid covering the LD and the PD.

### SUMMARY

An optical waveguide package according to an aspect of the present disclosure includes a substrate, a cladding on the substrate, a core in the cladding, a lid, and a metal member. The cladding includes a first surface facing the substrate, a second surface opposite to the first surface, and an element-receiving area being open in the second surface. The core extends from the element-receiving area. The lid covers the element-receiving area. The metal member is located between the cladding and the lid.

A light-emitting device according to another aspect of the present disclosure includes the above optical waveguide package, a light-emitting element in the element-receiving area, and a lens on an optical path of light to be emitted from the core.

### BRIEF DESCRIPTION OF THE DRAWINGS

FIG. 1 is an exploded perspective view of a light-emitting device including an optical waveguide package according to an embodiment of the present disclosure.

FIG. 2 is a perspective view of the light-emitting device in FIG. 1 without showing a lid.

FIG. 3 is a cross-sectional view of the light-emitting device taken along the section line in FIG. 2.

FIG. 4 is a plan view of the light-emitting device.

FIG. 5 is an enlarged plan view of an element-receiving area and its adjacent area in the optical waveguide package.

FIG. 6A is a plan view of an optical waveguide package according to another embodiment of the present disclosure.

FIG. 6B is a cross-sectional view of the optical waveguide package taken along the section line in FIG. 6A.

FIG. 7A is a plan view of a light-emitting device according to another embodiment of the present disclosure.

FIG. 7B is a cross-sectional view of the light-emitting device taken along the section line in FIG. 7A.

FIG. 8 is a cross-sectional view of a light-emitting device according to another embodiment of the present disclosure.

FIG. 9 is an exploded perspective view of a light-emitting device according to still another embodiment of the present disclosure.

FIG. 10 is a perspective view of the light-emitting device in FIG. 9 without showing a lid.

FIG. 11 is a cross-sectional view of the light-emitting device taken along the section line in FIG. 9.

FIG. 12 is a plan view of a light-emitting device according to a first variation of the embodiments of the present disclosure.

FIG. 13 is a cross-sectional view of the light-emitting device taken along the section line in FIG. 12.

FIG. 14 is a cross-sectional view of the optical waveguide package taken along the section line in FIG. 13.

FIG. 15 is a plan view of a light-emitting device according to a second variation of the embodiments of the present disclosure.

### DESCRIPTION OF EMBODIMENTS

A light-emitting device according to one or more embodiments of the present disclosure will now be described with reference to the accompanying drawings.

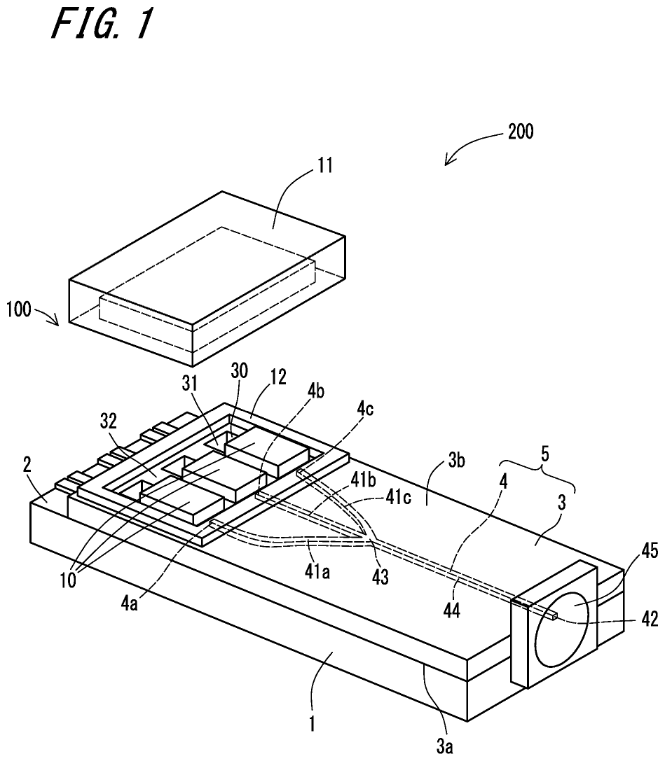

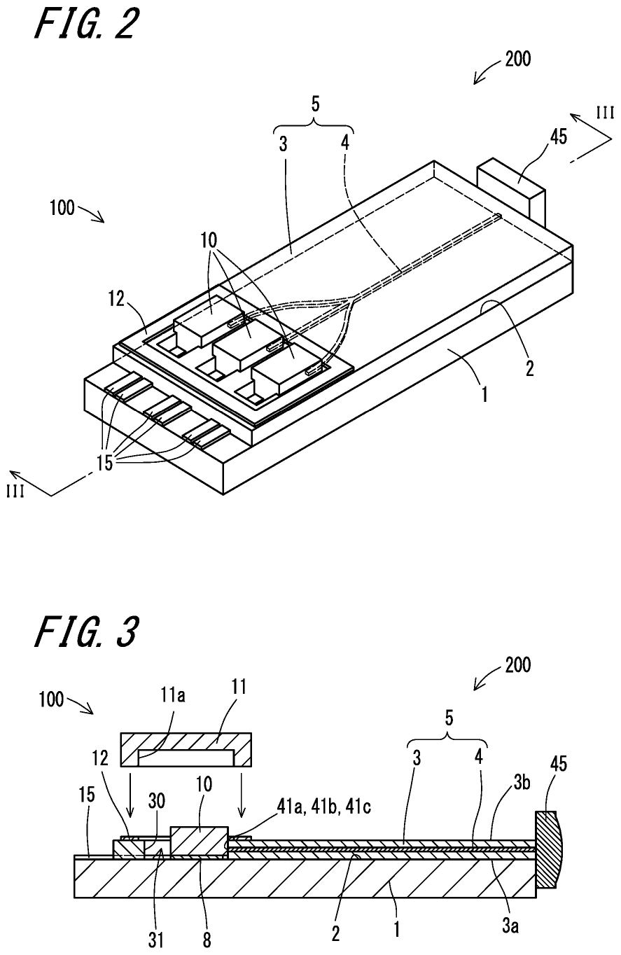

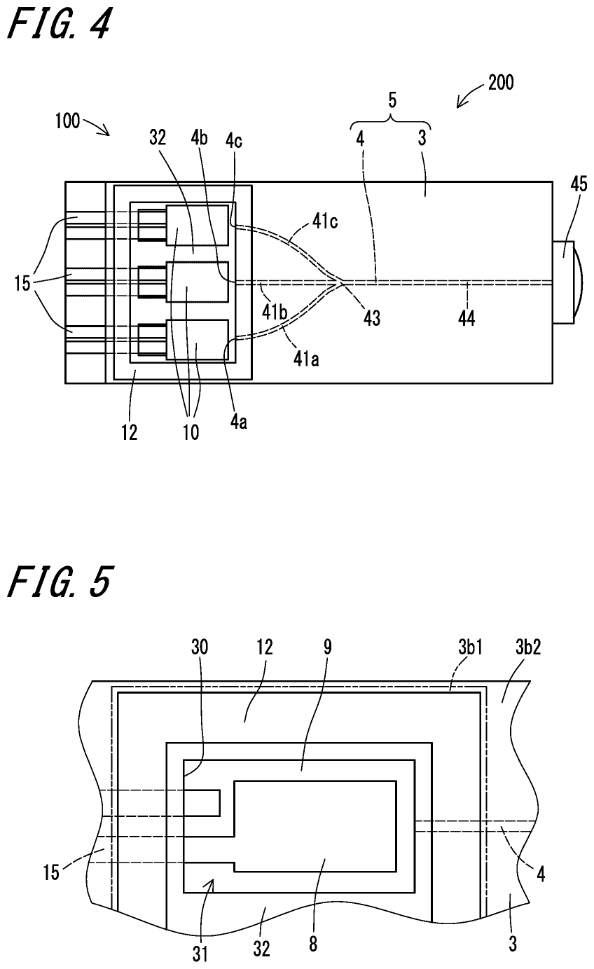

FIG. 1 is an exploded perspective view of a light-emitting device including an optical waveguide package according to an embodiment of the present disclosure. FIG. 2 is a perspective view of the light-emitting device in FIG. 1 without showing a lid. FIG. 3 is a cross-sectional view of the light-emitting device taken along the section line in FIG. 2. FIG. 4 is a plan view of the light-emitting device. FIG. 5 is an enlarged plan view of an element-receiving area and its adjacent area in the optical waveguide package.

An optical waveguide package 100 according to the present embodiment includes a substrate 1, an optical waveguide layer 5, a lid 11, and a metal member 12. The optical waveguide layer 5 is on an upper surface 2 of the substrate 1 and includes a cladding 3 and a core 4 in the cladding 3. The cladding 3 has a first surface 3a facing the substrate 1, a second surface 3b opposite to the first surface 3a, and an element-receiving area 9 that is open in the second surface 3b. The lid 11 covers the element-receiving area 9. The metal member 12 is between the cladding 3 and the lid 11.

The optical waveguide package 100 according to the present embodiment includes multiple (three in the present embodiment) element-receiving areas 9 each accommodating a light-emitting element 10. The optical waveguide package 100, the light-emitting elements 10 in the element-receiving areas 9, and a lens 45 on the optical path of the light emitted from the core 4 form a light-emitting device 200. The light-emitting elements 10 may be laser diodes. The optical waveguide package 100 according to the present embodiment accommodates three light-emitting elements 10. The light-emitting elements 10 emit light with respective colors, for example, red (R) light, green (G) light, or blue (B) light. The optical waveguide layer 5 includes the core 4 and the cladding 3 integral with each other. The substrate 1 may include multiple dielectric layers stacked on one another.

The substrate 1 may be a ceramic wiring board including dielectric layers formed from a ceramic material. Examples of the ceramic material used for the ceramic wiring board include sintered aluminum oxide, sintered mullite, sintered silicon carbide, sintered aluminum nitride, and sintered glass ceramic. For the substrate 1 being a ceramic wiring board, the dielectric layers include conductors such as connection pads, internal wiring conductors, and external connection terminals for electrical connection between the light-emitting and light-receiving elements and an external circuit.

The substrate 1 may be an organic wiring board including dielectric layers formed from an organic material. The organic wiring board may be a printed wiring board, a build-up wiring board, or a flexible wiring board. Examples of the organic material used for the organic wiring board include an epoxy resin, a polyimide resin, a polyester resin, an acrylic resin, a phenolic resin, and a fluororesin.

The optical waveguide layer 5 may be glass such as quartz, or a resin. In the optical waveguide layer 5, both the core 4 and the cladding 3 may be glass or a resin. In some embodiments, one of the core 4 and the cladding 3 may be glass and the other may be a resin. In the above case, the core 4 has a higher refractive index than the cladding 3. The difference in the refractive index causes total internal reflection of light. More specifically, a material with a higher refractive index is used to form a path, which is then surrounded by a material with a lower refractive index. This structure confines light in the core 4 with the higher refractive index.

The core 4 extends from the element-receiving areas 9 to allow light emitted from the light-emitting elements 10 on three element mounting portions 8 to be combined and reach the lens 45 in the present embodiment. For example, the core 4 in the present embodiment has three incident end faces 4a, 4b, and 4c corresponding to the respective element mounting portions 8, and one emission end face 42. The core 4 defines a merging path including branching paths 41a, 41b, and 41c, a merging portion 43, and a joined path 44 between the incident end faces 4a, 4b, and 4c and the emission end face 42. The branching paths 41a, 41b, and 41c respectively have the incident end faces 4a, 4b, and 4c at one end. The merging portion 43 merges the branching paths 41a, 41b, and 41c together. The joined path 44 has the emission end face 42 at one end.

Red (R) light, green (G) light, and blue (B) light emitted from the respective light-emitting elements 10 enter the respective branching paths 41a, 41b, and 41c through the incident end faces 4a, 4b, and 4c and pass through the merging portion 43 and the joined path 44 to the lens 45, through which the light is condensed and emitted.

The lens 45 is, for example, a plano-convex lens with a flat incident surface facing the core 4 and a convex emission surface. The optical waveguide layer 5, the light-emitting elements 10, and the lens 45 are assembled together to have the branching paths 41a, 41b, and 41c each with its optical axis aligned with the center of the light emitter of the corresponding light-emitting element 10, and to have the joined path 44 and the lens 45 with their optical axes aligned with each other.

In the present embodiment, the cladding 3 has through-holes 30 in the second surface 3b. In other words, the cladding 3 also has openings in the first surface 3a. The upper surface 2 of the substrate 1 and the through-holes 30 define compartments 31 for the light-emitting elements 10. Each compartment 31 has the element mounting portion 8 on the bottom. The element mounting portions 8 are used to join the light-emitting elements 10 to the upper surface 2 of the substrate 1. The element mounting portions 8 may include metal members such as metallized layers located on the upper surface 2 of the substrate. The metal members in the element mounting portions 8 are joined to the light-emitting elements 10 with a die bonding material such as a brazing material or an adhesive. In the present embodiment, the metal members in the element mounting portions 8 are connected to external wiring members 15. The light-emitting elements 10 include electrodes on the lower surfaces electrically connectable to the metal members in the element mounting portions 8 and further to, for example, an external power circuit through the external wiring members 15. The external wiring members 15 extend across inside and outside the compartments 31. The light-emitting elements 10 include electrodes on the upper surfaces that may be electrically connected to the external wiring members 15 (not connected to the metal members in the element mounting portions 8) with, for example, bonding wires (not shown).

The lid 11 for covering the element-receiving areas 9 is on the second surface 3b of the cladding 3. The metal member 12 surrounds the element-receiving areas 9 between the lid 11 and the cladding 3 to improve airtightness in the compartments 31 accommodating the light-emitting elements 10. In the present embodiment, the metal member 12 is, for example, in a continuous loop and surrounds the through-holes 30 in a plan view. The cladding 3 and the second surface 3b joined together with the metal member 12 allow the compartments 31 to be more airtight than the cladding 3 and the lid 11 joined together with, for example, a resin adhesive. The lid 11 may be formed from a glass material such as quartz, borosilicate, or sapphire.

The lid 11 may have a recess 11a. In the present embodiment, for example, the lid 11 has the recess 11a facing the element-receiving areas 9. The light-emitting elements 10 extend from the element-receiving areas 9 into the recess 11a. The light-emitting elements 10 received in the element-receiving areas 9 may have a greater height than the cladding 3, or in other words, the light-emitting elements 10 may protrude from the second surface 3b of the cladding 3. The lid 11 receives the protruding areas in the recess 11a and can thus be joined to the cladding 3 with the metal member 12 in between. In other words, the lid 11 with the above structure allows the cladding 3 to be thinner. The lid 11 is located on a first region 3b1 of the cladding 3 and thus reduces the height of the light-emitting device 200.

In the present embodiment, the metal member 12 is located on the second surface 3b of the cladding 3. In this case, for example, the metal member 12 is formed from Ti, Ni, Au, Pt, or Cr, or two or more of these metals, and is fixed on the second surface 3b of the cladding 3 by vapor deposition, sputtering, ion plating, or plating. The lid 11 is joined to the metal member 12 by, for example, thermal curing or laser welding using a bond, such as Au—Sn or Sn—Ag—Cu solder, a metal nanoparticle paste of Ag or Cu, or a glass paste.

The metal member 12 may be located on the lid 11, rather than on the cladding 3, in an area facing the cladding 3. In this case, for example, the metal member 12 is formed from Ti, Ni, Au, Pt, or Cr, or two or more of these metals, and is fixed on the lid 11 by vapor deposition, sputtering, ion plating, or plating. The cladding 3 is joined to the metal member 12 by, for example, thermal curing or laser welding using a bond, such as Au—Sn or Sn—Ag—Cu solder, a metal nanoparticle paste of Ag or Cu, or a glass paste.

The metal member 12 may be located on both the cladding 3 and the lid 11. In this case, the metal member 12 on the cladding 3 is joined to the metal member 12 on the lid 11 by, for example, thermal curing or laser welding using a bond, such as Au—Sn or Sn—Ag—Cu solder, a metal nanoparticle paste of Ag or Cu, or a glass paste.

In the present embodiment, for example, the second surface 3b of the cladding 3 includes the first region 3b1 surrounding the element-receiving areas 9 in a plan view and a second region 3b2 other than the first region 3b1. The lid 11 is located only on the first region 3b1. This structure allows the second region 3b2 to be at a lower height than with the lid 11 extending over the entire second surface 3b including the second region 3b2. The lid 11 may extend over the entire second surface 3b to protect the second surface 3b of the cladding 3.

One compartment 31 may include multiple element mounting portions 8. In other words, such multiple element mounting portions 8 are located in one of the through-holes 30 in a plan view. In the present embodiment, one compartment 31 includes multiple element mounting portions 8 and partitions 32 each between the element-receiving areas 9. The compartment 31, separated by the partitions 32, has spaces defined for the respective element mounting portions 8 to receive the light-emitting elements 10. In other words, the multiple element-receiving areas 9 are separated by the partitions 32 for receiving the light-emitting elements 10. Light emitted from one light-emitting element 10 may be partially reflected without entering the incident end face 4a of the core 4, possibly causing stray light in the compartment 31. This may affect the other light-emitting elements 10. The partitions 32 can reduce the effects of such stray light. The cladding 3 may receive thermal stress upon being heated when, for example, the light-emitting elements 10 are operating, the lid 11 is joined to the cladding 3, or the light-emitting elements 10 are mounted on the element mounting portions 8. The thermal stress may cause deformation of the element-receiving areas 9 and their adjacent areas in the cladding 3, possibly causing cracks, peeling of the metal member 12, or peeling of the cladding from the substrate 1. This may also reduce the airtightness. The partitions 32 can increase the heat transfer paths to dissipate heat, reduce deformation of the cladding 3 under thermal stress, and lower the likelihood of airtightness reduction.

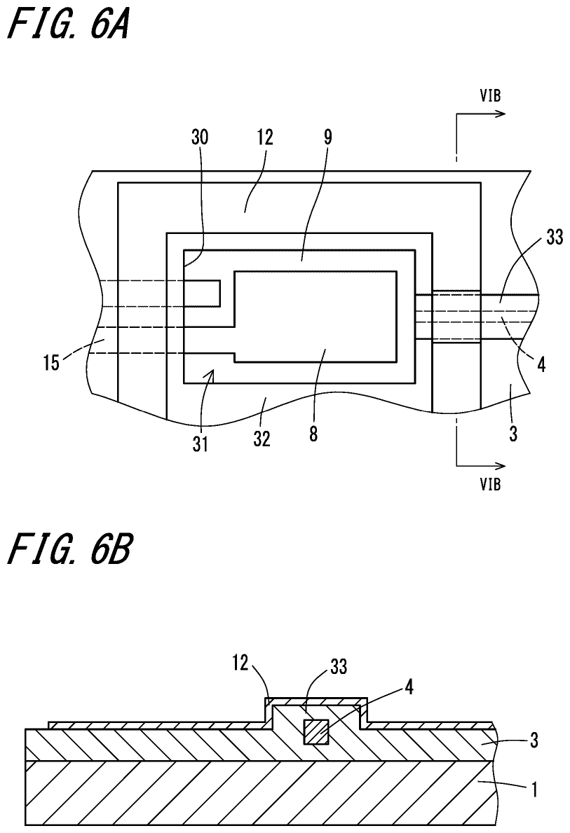

FIG. 6A is a plan view of an optical waveguide package according to another embodiment of the present disclosure. FIG. 6B is a cross-sectional view of the optical waveguide package taken along the section line in FIG. 6A. The components corresponding to those in the above embodiments are given the same reference numerals and will not be described repeatedly. In the optical waveguide package according to the present embodiment, the cladding 3 includes a protrusion 33 above the core 4. The protrusion 33 protrudes from the second surface 3b of the cladding 3. The protrusion 33 is above the core 4 (adjacent to the second surface 3b). The core 4 may be at least partially within the protrusion 33. The protrusion 33 may be in, for example, the first region 3b1 and the second region 3b2 and may extend along the core 4.

For the cladding 3 with the metal member 12, the metal member 12 extends along the surface of the protrusion 33. For the lid 11 having a flat surface facing the cladding 3, the bond between the lid 11 and the metal member 12 is thinner on the protrusion 33 than on the other area. In other words, the protrusion 33 has a smaller amount of bond on its surface than the other area. Heat applied to join the lid 11 transfers through the bond and the metal member 12 to the cladding 3. The protrusion 33 having the smaller amount of bond reduces heat transferring to the core 4 below the protrusion 33, thus lowering the likelihood of deteriorating optical transmission characteristics under heat.

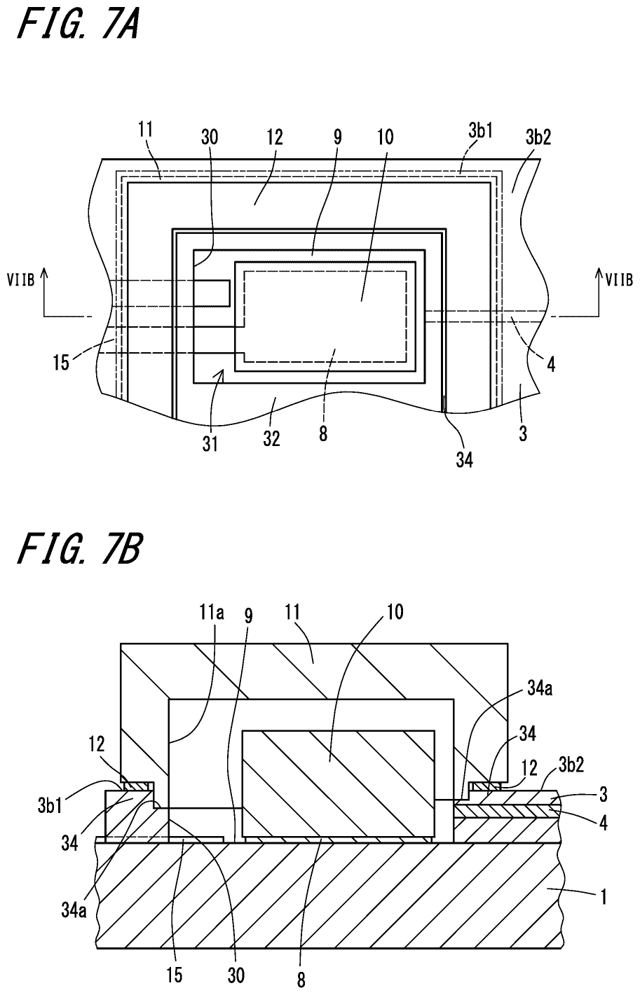

FIG. 7A is a plan view of a light-emitting device according to another embodiment of the present disclosure. FIG. 7B is a cross-sectional view of the light-emitting device taken along the section line in FIG. 7A. The components corresponding to those in the above embodiments are given the same reference numerals and will not be described repeatedly. In the light-emitting device according to the present embodiment, the cladding 3 includes, in the first region 3b1, a step 34 fitted with the lid 11. This structure increases the strength for joining the lid 11 to the cladding 3 with the metal member 12 in between. The step 34 may have any shape to fit to the lid 11. In the present embodiment, for example, the step 34 has a step surface 34a defined by an inner portion of the first region 3b1 (an edge of the through-hole 30) one step lower and closer to the first surface 3a of the cladding 3. The lid 11 may have any shape to fit to the step 34. For example, the lid 11 may include a step shaped in correspondence with the step 34. The metal member 12 may be located entirely or partially on the step 34. In the present embodiment, for example, the metal member 12 may be on an outer portion of the first region 3b1 (a portion surrounding the step surface 34a) without being located on the step surface 34a.

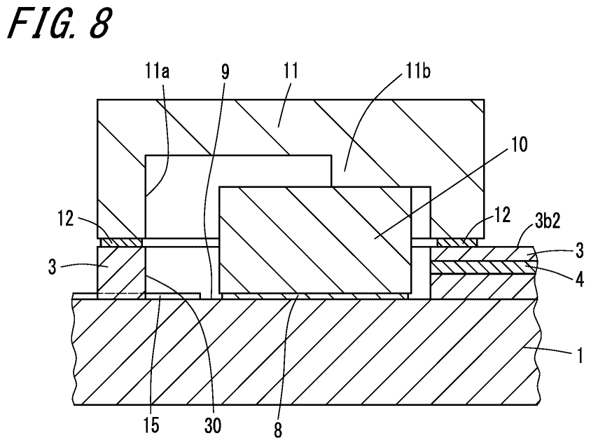

FIG. 8 is a cross-sectional view of a light-emitting device according to another embodiment of the present disclosure. The components corresponding to those in the above embodiments are given the same reference numerals and will not be described repeatedly. In the light-emitting device according to the present embodiment, the lid 11 includes a contact portion 11b in contact with the light-emitting elements 10. The contact portion 11b protrudes outward from the surface of the lid 11 facing the element-receiving areas 9. In the present embodiment, the lid 11 has a recess 11a receiving the contact portion 11b. The lid 11 joined to the cladding 3 with the metal member 12 in between may have the contact portion 11b in contact with the light-emitting elements 10. For the lid 11 with no contact portion 11b, the operating light-emitting elements 10 generate heat that mainly transfers through the element mounting portions 8 to the substrate 1 for dissipation. For the lid 11 with the contact portion 11b, the operating light-emitting elements 10 generate heat that transfers through the element mounting portions 8 to the substrate 1 and also transfers through the contact portion 11b to the lid 11 for dissipation, for example, from the surface of the lid 11. This reduces the effects of heat from the operating light-emitting elements 10.

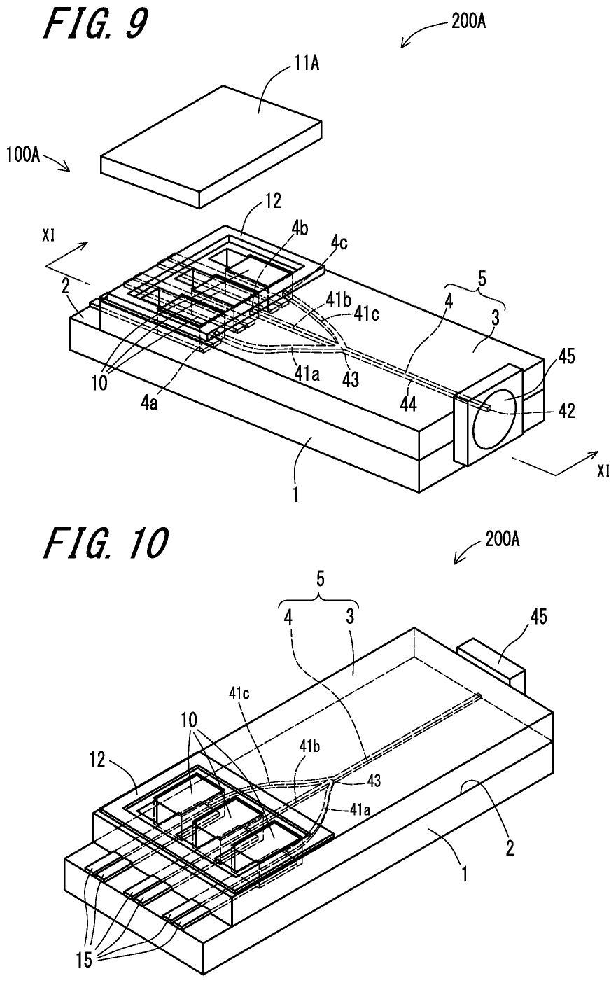

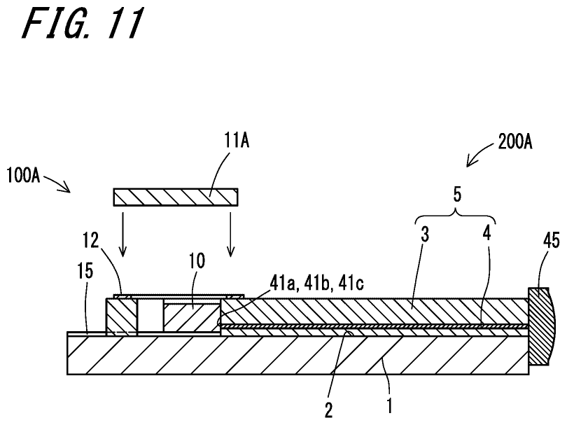

FIG. 9 is an exploded perspective view of a light-emitting device 200A according to still another embodiment of the present disclosure. FIG. 10 is a perspective view of the light-emitting device 200A in FIG. 9 without showing a lid 11A. FIG. 11 is a cross-sectional view of the light-emitting device 200A taken along the section line in FIG. 9. The components corresponding to those in the above embodiments are given the same reference numerals and will not be described repeatedly. In the above embodiments, the light-emitting elements 10 include upper portions protruding from the cladding 3. The protruding portions are received in the recess 11a in the lid 11. In the present embodiment, for example, an optical waveguide package 100A includes a cladding 3 thicker than the light-emitting elements 10. The compartments 31 each accommodate the entire light-emitting element 10 and are covered with a plate-like lid 11A. This structure allows the lid 11A to have no recess 11a and thus simplifies the lid 11A.

In still another embodiment of the present disclosure, a light-emitting device 200 may include a thermistor. For example, the thermistor may be located to detect the temperature of the optical waveguide layer 5, or may be located in each compartment 31 to detect the temperature of the light-emitting element 10, or may be located on each external wiring member 15 outside the compartments 31. The light-emitting device 200 may also include a light-receiving element in each compartment 31. A light-receiving element is located opposite to the incident end face 4a from a light-emitting element 10. The light-emitting element 10 emits light toward the incident end face 4a and simultaneously emits the same light in the opposite direction. The light-receiving element can receive and observe the light from the light-emitting element 10 to control the output from the light-emitting element 10.

In still another embodiment of the present disclosure, the light-emitting elements 10 are not limited to light-emitting diodes (LEDs) but may be, for example, laser diodes (LDs) or vertical cavity surface emitting lasers (VCSELs).

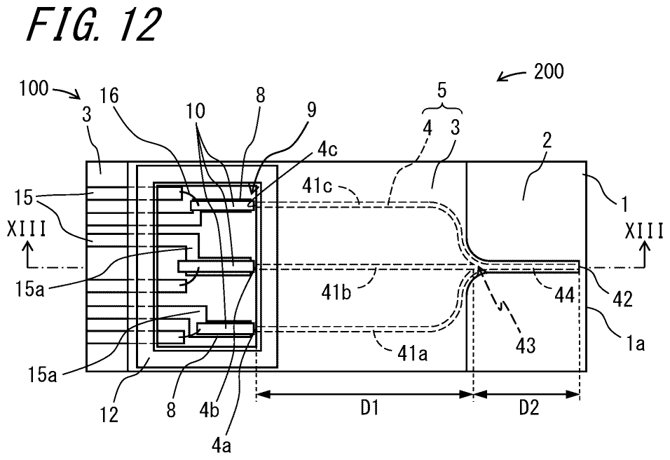

FIG. 12 is a plan view of a light-emitting device 200 and an optical waveguide package 100 according to a first variation of the embodiments of the present disclosure. In the first variation, the optical waveguide package 100 includes a single element-receiving area 9. As in the embodiments of the present disclosure, the optical waveguide package 100 according to the first variation includes the merging portion 43 located outside an area surrounded by the metal member 12. More specifically, the core 4 includes the first incident end face 4a, the second incident end face 4b, and the emission end face 42. The first incident end face 4a and the second incident end face 4b are exposed in the element-receiving area 9. The emission end face 42 is connected to the first incident end face 4a and the second incident end face 4b with a waveguide. The waveguide includes a first branching path 41a connected to the first incident end face 4a, a second branching path 41b connected to the second incident end face 4b, and the merging portion 43 merging the first branching path 41a and the second branching path 41b. In FIG. 12, the first branching path 41a is linear, and the second branching path 41b is curved. However, the first branching path 41a may be curved in the same manner as or in a similar manner to the second branching path 41b. Note that the optical waveguide package 100 according to the first variation may include a third branching path 41c.

In the merging portion 43, light traveling through each of the branching paths is relatively likely to scatter and may cause lower light efficiency. When the metal member 12 is formed on the cladding 3, the cladding 3 may deform slightly. When the cladding 3 deforms, the core 4 immediately below the metal member 12 also deforms. This may disturb light traveling through the core 4 and lower the light efficiency of the light emitted from the core 4. Thus, the merging portion 43, in which light efficiency is likely to decrease, located distant from the metal member 12 can reduce the likelihood that light traveling through the merging portion 43 is disturbed and light emitted from the core 4 causes lower light efficiency.

The waveguide may further include the joined path 44 extending from the merging portion 43 to the emission end face 42. In this case, a distance D1 from the first incident end face 4a to the merging portion 43 may be greater than a distance D2 from the merging portion 43 to the emission end face 42 as illustrated in FIG. 12. Note that the distance from the second incident end face 4b to the merging portion 43 may also be greater than the distance D2 from the merging portion 43 to the emission end face 42. In one or more embodiments of the present disclosure, the first incident end face 4a, the second incident end face 4b, and a third incident end face 4c may or may not be on the same straight line as in FIG. 12, and may be displaced from one another.

The joined path 44 described above may be linear from the merging portion 43 to the emission end face 42 as illustrated in FIG. 4 or FIG. 12. The joined path 44 may have a uniform width, or may include a tapered portion having a width gradually decreasing toward the emission end face 42.

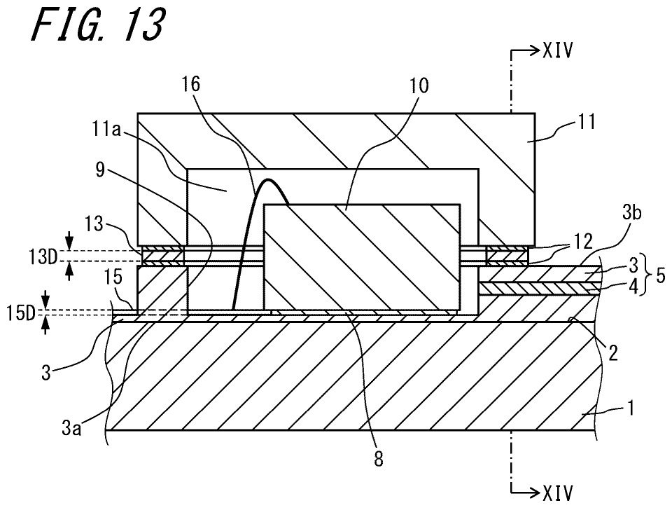

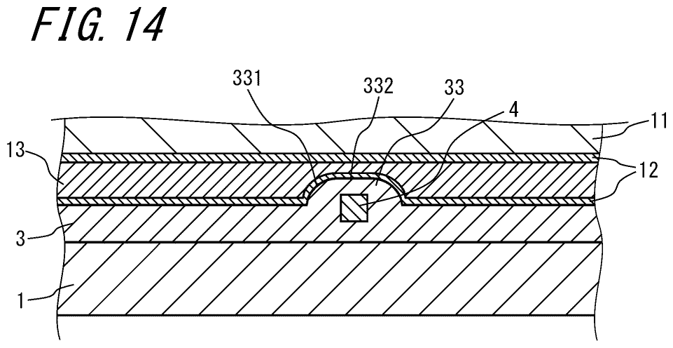

As illustrated in FIGS. 12 and 13, the optical waveguide package 100 according to the first variation may include the element-receiving area 9 that is not through the cladding 3. In other words, the element-receiving area 9 may be a recess on the second surface 3b.

In the first variation, the optical waveguide package 100 may further include the external wiring members 15 in the element-receiving area 9. In this case, the external wiring members 15 may extend through the cladding 3 to outside the element-receiving area 9 as illustrated in FIGS. 12 and 13. More specifically, the external wiring members 15 may be on a bottom surface of the element-receiving area 9 and be partially embedded in the cladding 3. At least two external wiring members 15 may be electrically connected to one light-emitting element 10. When one of the external wiring members 15 includes the element mounting portion 8 receiving a die-bonded light-emitting element 10, the other external wiring member 15 may be electrically connected to the light-emitting element 10 with a bonding wire 16.

In the optical waveguide package 100 according to the first variation further including the external wiring members 15 in the element-receiving area 9, the external wiring members 15 may include the element mounting portion 8 extending in a first direction (a direction in which the core 4 extends in the drawings) and a bent portion 15a connected to the element mounting portion 8 and extending in a direction intersecting with the first direction.

As illustrated in FIG. 13, the metal member 12 may also be at a position at which the lid 11 faces the cladding 3. The metal member 12 on the lid 11 may be made of a material that is the same as or different from the material of the metal member 12 on the cladding 3. The metal member 12 on the lid 11 may be joined to the metal member 12 on the cladding 3 with a bond 13 between them. The bond 13 may be, for example, a bond containing gold-tin.

In the optical waveguide package 100 according to the first variation, the bond 13 may have a thickness 13D thicker than a thickness 15D of the external wiring member 15. With this structure, the bond 13 serves as cushioning when the lid 11 is mounted on the cladding 3, reducing deformation of the cladding 3.

In the optical waveguide package 100 according to the first variation, as illustrated in FIG. 12, the substrate 1 may be exposed between the merging portion 43 and the emission end face 42 in a plan view. This structure can reduce the likelihood that light leaking from the core 4 travels through the cladding 3 and unintended light mixes with light emitted from the emission end face 42.

As illustrated in FIG. 12, the substrate 1 includes a front portion 1a adjacent to the emission end face 42. The front portion 1a may extend beyond the emission end face 42 in a plan view. With this structure, a component approaching the emission end face 42 may collide with the front portion 1a first, reducing the likelihood of damaging the emission end face 42.

As illustrated in FIG. 14, the cladding 3 includes a protrusion 33 above the core 4. The protrusion 33 may include a curved portion 331 that is curved more at a position farther from the core 4 in a cross-sectional view. The protrusion 33 may further include a linear flat portion 332 above the core 4. The curved portion 331 and the flat portion 332 may extend along the core 4.

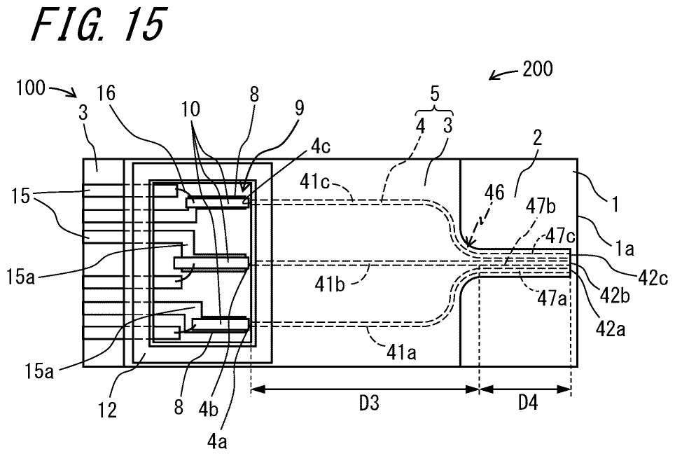

FIG. 15 is a plan view of a light-emitting device 200 and an optical waveguide package 100 according to a second variation of the embodiments of the present disclosure. Unlike in the embodiments of the present disclosure and the first variation, the optical waveguide package 100 according to the second variation includes the first incident end face 4a, the second incident end face 4b, a first emission end face 42a, a second emission end face 42b, and the core 4. The first incident end face 4a and the second incident end face 4b are exposed in the element-receiving area 9. The first emission end face 42a is connected to the first incident end face 4a with a first waveguide. The second emission end face 42b is connected to the second incident end face 4b with a second waveguide. The core 4 is located in the cladding 3. The core 4 further includes a convergence portion 46 in which the first waveguide and the second waveguide are closest to each other. The convergence portion 46 is located outside an area surrounded by the metal member 12. In the second variation, the core 4 may further include a third incident end face 4c, a third waveguide, and a third emission end face 42c. The convergence portion 46 can be defined as a portion in which multiple cores are closest to one another.

The waveguide may further include a first emission portion 47a extending from the convergence portion 46 to the first emission end face 42a. The first emission portion 47a may extend linearly in parallel to a direction in which light is emitted from the core 4. The first emission portion 47a may have a uniform width. The waveguide may also include a second emission portion 47b extending from the convergence portion 46 to the second emission end face 42b, and a third emission portion 47c extending from the convergence portion 46 to the third emission end face 42c. In this case, the second emission portion 47b and the third emission portion 47c may also extend linearly in parallel to the direction in which light is emitted from the core 4. The second emission portion 47b may have a uniform width. The third emission portion 47c may also have a uniform width. Note that the first emission portion 47a, the second emission portion 47b, and the third emission portion 47c may have different widths.

A distance D3 from the first incident end face 4a to the convergence portion 46 may be greater than a distance D4 from the convergence portion 46 to the first emission end face 42a. Note that the distance from the second incident end face 4b to the convergence portion 46 may be greater than the distance from the convergence portion 46 to the second emission end face 42b, and the distance from the third incident end face 4c to the convergence portion 46 may be greater than the distance from the convergence portion 46 to the third emission end face 42c. In one or more embodiments of the present disclosure, the first incident end face 4a, the second incident end face 4b, and the third incident end face 4c may or may not be on the same straight line as in FIG. 15, and may be displaced from one another. The first emission end face 42a, the second emission end face 42b, and the third emission end face 42c may or may not be on the same straight line as in FIG. 15, and may be displaced from one another.

Although embodiments of the present disclosure have been described in detail, the present disclosure is not limited to the embodiments described above, and may be changed or varied in various manners without departing from the spirit and scope of the present disclosure. The components described in the above embodiments and variations may be entirely or partially combined as appropriate unless any contradiction arises.

### REFERENCE SIGNS

1 substrate
1a front portion
2 upper surface
3 cladding
3a first surface
3b second surface
4 core
4a, 4b, 4c incident end face
5 optical waveguide layer
8 element mounting portion
9 element-receiving area
10 light-emitting element
11, 11A lid
11a recess
11b contact portion
12 metal member
13 bond
15 external wiring member
15a bent portion
16 bonding wire
30 through-hole
31 compartment
32 partition
33 protrusion
331 curved portion
332 flat portion
34 step
34a step surface
3b1 first region
3b2 second region
41a, 41b, 41c branching path
42 emission end face
43 merging portion
44 joined path
45 lens
46 convergence portion
47a, 47b, 47c emission portion
100, 100A optical waveguide package
200, 200A light-emitting device

1. An optical waveguide package, comprising:
a substrate;
a cladding on the substrate, the cladding including a first surface facing the substrate, a second surface located opposite to the first surface, and an element-receiving area being open in the second surface;
a core in the cladding, the core including a first incident end face, a second incident end face, and an emission end face, the first incident end face and the second incident end face being exposed in the element-receiving area, the emission end face being connected to the first incident end face and the second incident end face with a waveguide; and
a metal member located on the second surface and surrounding the element-receiving area,
wherein the waveguide includes
a first branching path connected to the first incident end face,
a second branching path connected to the second incident end face, and
a merging portion merging the first branching path and the second branching path, and
the merging portion is outside an area surrounded by the metal member.

2. The optical waveguide package according to claim 1, wherein the waveguide further includes a joined path extending from the merging portion to the emission end face, and
a distance from the first incident end face to the merging portion is greater than a distance from the merging portion to the emission end face.

3. The optical waveguide package according to claim 1, further comprising:
an external wiring member in the element-receiving area, the external wiring member extending through the cladding to outside the element-receiving area.

4. The optical waveguide package according to claim 1, wherein
the substrate is exposed between the merging portion and the emission end face in a plan view.

5. The optical waveguide package according to claim 1, wherein
the element-receiving area is included in the cladding without extending through the cladding.

6. The optical waveguide package according to claim 1, wherein
the substrate includes a front portion adjacent to the emission end face, and
the front portion extends beyond the emission end face in a plan view.

7. The optical waveguide package according to claim 1, wherein
the cladding includes a protrusion above the core.

8. The optical waveguide package according to claim 7, wherein
the protrusion includes a curved portion being curved more at a position farther from the core in a cross-sectional view.

9. The optical waveguide package according to claim 1, further comprising:
an external wiring member in the element-receiving area, the external wiring member including
an element mounting portion extending in a first direction, and
a bent portion connected to the element mounting portion and extending in a direction intersecting with the first direction.

10. A light-emitting device, comprising:
the optical waveguide package according to claim 1; and
a light-emitting element in the element-receiving area.

11. An optical waveguide package, comprising:
a substrate;
a cladding on the substrate, the cladding including a first surface facing the substrate, a second surface located opposite to the first surface, and an element-receiving area being open in the second surface;
a core in the cladding, the core including a first incident end face, a second incident end face, a first emission end face, and a second emission end face, the first incident end face and the second incident end face being exposed in the element-receiving area, the first emission end face being connected to the first incident end face with a first waveguide, the second emission end face being connected to the second incident end face with a second waveguide; and
a metal member located on the second surface and surrounding the element-receiving area,
wherein the core further includes a convergence portion in which the first waveguide and the second waveguide are closest to each other, and
the convergence portion is outside an area surrounded by the metal member.

12. The optical waveguide package according to claim 11, wherein
a distance from the first incident end face to the convergence portion is greater than a distance from the convergence portion to the first emission end face.

13. The optical waveguide package according to claim 11, further comprising:
an external wiring member in the element-receiving area, the external wiring member extending through the cladding to outside the element-receiving area.

14. The optical waveguide package according to claim 11, wherein
the substrate is exposed between the merging portion and the first and second emission end faces in a plan view.

15. The optical waveguide package according to claim 11, wherein
the element-receiving area is not through the cladding.

16. The optical waveguide package according to claim 11, wherein
the substrate further includes a front portion adjacent to the first and second emission end faces, and
the front portion extends beyond the first and second emission end faces in a plan view.

17. The optical waveguide package according to claim 11, wherein
the cladding includes a protrusion above the core.

18. The optical waveguide package according to claim 17, wherein
the protrusion includes a curved portion being curved more at a position farther from the core in a cross-sectional view.

19. The optical waveguide package according to claim 11, further comprising:
an external wiring member in the element-receiving area, the external wiring member including
an element mounting portion extending in a first direction, and
a bent portion connected to the element mounting portion and extending in a direction intersecting with the first direction.

20. A light-emitting device, comprising:
the optical waveguide package according to claim 11; and
a light-emitting element in the element-receiving area.
